(19) United States
(12) Patent Application Publication
(10) Pub. No.: US 2021/0028159 A1
(43) Pub. Date: Jan. 28, 2021

(54) SYMMETRICAL LAYOUT STRUCTURE OF SEMICONDUCTOR DEVICE

(71) Applicant: NATIONAL CHENG KUNG UNIVERSITY, TAINAN CITY (TW)

(72) Inventors: Hung-Yi Huang, TAINAN CITY (TW); Tai-Haur Kuo, TAINAN CITY (TW)

(21) Appl. No.: 16/522,635

(22) Filed: Jul. 25, 2019

(51) Int. Cl. H01L 27/02; H01L 49/02; H01L 27/06; H03M 1/66

(52) U.S. Cl. CPC H01L 27/0207; H01L 28/40; H03M 1/66; H01L 28/10; H01L 27/0629; H01L 28/20

(57) ABSTRACT

A symmetrical layout structure of a semiconductor device is formed on a chip. The symmetrical layout structure is performed in a (2^{M+1})×(2^{M+1}) array and comprises 2^{M}−r working units and r dummy unit(s). Each working unit has 2^{2+M} sub-working units continuously connected by a closed trace and arranged along the closed trace in the array, wherein M is a positive integer, and r is zero or a positive integer. Each closed trace forms a parallelogram that is symmetrical to a diagonal path of the array. The working unit can be a current cell. According to the layout structure, all parallelograms have the same centroid, the perimeters of all parallelograms are the same, the lengths of the closed traces are the same, and the distances between all of the sub-current cells are the same. The present invention thus improves the performance of the digital-to-analog converter.

### BACKGROUND OF THE INVENTION

### 1. Field of the Invention

The present invention relates to a layout structure, and more particularly to a symmetrical layout structure of a semiconductor device.

### 2. Description of Related Art

Semiconductor device, such as a digital-to-analog converter (hereinafter referenced as DAC), is a converter that converts a digital signal to an analog signal. With reference to FIG. 18, the DAC 30 is connected to a filter 31 and an amplifier 32 in series. The DAC 30 receives a digital signal and converts it into an analog signal that is filtered by the filter 31 and amplified by the amplifier 32. With reference to FIG. 19, a current steering DAC is disclosed. The current steering DAC comprises a decoder 41, a switch driver 42 and a current cell array 43 connected in series. The current cell array 43 consists of multiple current cells 430. The decoder 41 has M input terminals for receiving an M-bit digital signal, wherein M is a positive integer for representing the resolution of the current steering DAC. After the decoder 41 decodes the digital signal, a decoding result is transmitted to the switch driver 42. The switch driver 42 sends driving signals to activate the current cells 430 according to the decoding result. With reference to FIG. 20, the equivalent circuit model of each of the current cells 430 comprises two electric switches 431 and a current source 432. The electric switches 431 can be MOSFETs (Metal-Oxide-Semiconductor Field-Effect Transistor). The switch driver 42 is electrically connected to the gates of the electric switches 431 of each current cell 430, thereby turning on or turning off one of the electric switches 431 of each current cell 430 according to the decoding result. Hence, the current cell array 43 outputs the analog signal obtained from the current sources 432 of the multiple current cells 430. The current cell array is manufactured by semiconductor process and formed on a wafer or a chip. However, the performances of the current cells vary, such that the outputted analog signals from the current cells are not homogeneous. For example, some of the current cells may output higher currents and others may output lower currents. On the whole, the current cell array fails to homogeneously output the analog signal. A defect of gradient mismatch occurs. In order to overcome the defect mentioned above, with reference to FIG. 21, a first conventional layout structure is disclosed. The DAC is a 3-bit DAC that has seven current cells. In the first conventional layout structure, each current cell is composed of 32 sub-current cells. The sub-current cells in a first current cell are named as M1. The sub-current cells in a second current cell are named as M2. The sub-current cells of the remaining current cells are respectively named as M3-M7. As the layout structure disclosed in FIG. 21, the 16×16 sub-current cells are divided into sixteen regions, wherein each region has 4×4 sub-current cells. These regions have been optimized to compensate for the quadratic-like mismatch. By random walking through the 16×16 sub-current cells, the mismatch is not accumulated but rather randomized, hence the name Q² random walk.

With reference to FIG. 22, a second conventional layout structure is disclosed. The DAC is a 3-bit DAC that has seven current cells. Each current cell has 8 sub-current cells. The sub-current cells of the seven current cells are formed in an array. The sub-current cells in the first current cell are named as M1. The sub-current cells in the second current cell are named as M2. The sub-current cells of the remaining current cell are respectively named as M3-M7. As shown in FIG. 22, seven sub-current cells M1 of the first current cell are obliquely arranged, and the remaining one is located on a corner of the array. Seven sub-current cells M2 of the second current cell are arranged adjacent to the seven current cells M1 and the remaining one is located on another corner of the array. Since the sub-current cells of each of the seven current cells “walk” through all the eight x and y coordinates (with different offsets), the mismatch contributes the same sum to all current cells, and the analog signal output from the current cell array can be averaged to overcome the gradient mismatch. However, with reference to FIG. 23, in the first conventional layout structure and taking the sub-current cells M1 and M2 as examples, the sub-current cells M1 are electrically connected by a driving wire 50, and the sub-current cells M2 are electrically connected by a driving wire 60. The parasitic capacitors and parasitic resistors of the driving wires induce the delay for driving signals. Because the lengths of driving wires 50 and 60 are different, the timing for driving signals reaching sub-current cells M1 is not the same as the timing for driving signals reaching sub-current cells M2, and thus degrading the performance of the DAC (called timing skew defect).

Similarly, with reference to FIG. 24, in the second conventional layout structure, a first driving wire 61 is connected to the current cells M1 and a second driving wire 62 is connected to the current cells M2. Even though the lengths of the driving wires 61 and 62 are the same, the distance between a first sub-current cell referenced as M_{1_1} and a second sub-current cell referenced as M_{1_2} of the current cell M1 is much longer than the distance between a first sub-current cell referenced as M_{2_1} and a second sub-current cell referenced as M_{2_2} of the current cell M2. Therefore, the second conventional layout structure still has the timing skew defect.

### SUMMARY OF THE INVENTION

An objective of the present invention is to provide a symmetrical layout structure of a semiconductor device to overcome the gradient mismatch and timing skew defect.

The symmetrical layout structure is formed on a chip. The symmetrical layout structure is performed in a (2^{M+1})×(2^{M+1}) array and comprises 2^{M}-r working units and r dummy unit(s). Each working unit has 2^{2+M} sub-working units continuously connected by a closed trace and arranged along the closed trace in the array, wherein M is a positive integer, and r is zero or a positive integer. Each closed trace forms a parallelogram that is symmetrical to a diagonal path of the array.

The placement of the sub-working units of each working unit forms a parallelogram, and the mismatch of each side is used to compensate the mismatch of the opposite side. For example, the working unit and sub-working unit are current cell and sub-current cells respectively. Since all parallelograms have the same centroid, the currents of the current cells are similar to each other. Moreover, the perimeters of all parallelograms are the same, and so the lengths of the closed traces of the current cells are the same. Further, the distances between all of the sub-current cells are the same. Compared with the conventional layout structure, the present invention has better performance in overcoming timing skew effect, and can improve the performance of the digital-to-analog converter.

### BRIEF DESCRIPTION OF THE DRAWINGS

FIG. 1 is a schematic view of a symmetrical layout structure of the present invention, formed on a chip;

FIG. 2 is a layout structure of a first embodiment of the present invention; FIG. 3 is a schematic view showing that the sub-current cells of the current cells M1 and M2 are connected by driving wires;

FIG. 4 is a layout structure of a second embodiment of the present invention;

FIG. 5 is a schematic view showing the sub-current cells of the current cell M1 are connected by a driving wire;

FIG. 6 is a schematic view showing the sub-current cells of the current cell M2;

FIG. 7 is a schematic view showing the sub-current cells of the current cell M3;

FIG. 8 is a schematic view showing the sub-current cells of the current cell M4;

FIG. 9 is a schematic view showing the sub-current cells of the current cell M5;

FIG. 10 is a schematic view showing the sub-current cells of the current cell M6;

FIG. 11 is a schematic view showing the sub-current cells of the current cell M7;

FIG. 12 is circuit block diagram of a 14-bit current steering DAC;

FIG. 13 is a waveform diagram of a simulating result of a conventional layout structure of a DAC;

FIG. 14 is a waveform diagram of a simulating result of the layout structure of the present invention;

FIG. 15 is a circuit symbol of a sub-capacitor unit;

FIG. 16 is a circuit symbol of a sub-resistor unit;

FIG. 17 is a circuit symbol of a sub-inductor unit;

FIG. 18 is a circuit block diagram of a DAC connected to a filter and an amplifier;

FIG. 19 is a circuit block diagram of a current steering DAC;

FIG. 20 is a circuit block diagram of a current cell;

FIG. 21 is a schematic view of a first conventional layout structure of a DAC;

FIG. 22 is a schematic view of a second conventional layout structure of a DAC;

FIG. 23 is a schematic view showing the current cells M1 and M2 of FIG. 21 connected by driving wires; and

FIG. 24 is a schematic view showing the current cells of FIG. 22 connected by driving wires.

### DETAILED DESCRIPTION OF THE PREFERRED EMBODIMENT

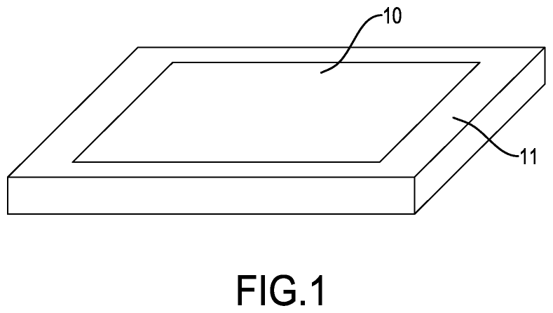

With reference to FIG. 1, a symmetrical layout structure 10 of the present invention is formed on a chip 11. The symmetrical layout structure 10 is performed in a (2^{M+1})×(2^{M+1}) array, and comprises 2^{M}-r working units and r dummy unit(s),wherein M is a positive integer and r is zero or a positive integer. Each working unit has 2^{2+M} sub-working units continuously connected by a closed trace and arranged along the closed trace in the array. Each closed trace forms a parallelogram that is symmetrical to a diagonal path of the array. Each dummy unit has multiple dummy elements. In the present invention, the position of each sub-working unit and dummy element is represented as (x,y) in the array, wherein x is a row number of the array, and y is a column number of the array. The diagonal path goes through sub-working units including (1, 2^{M+1}) and (2^{M+1},1).

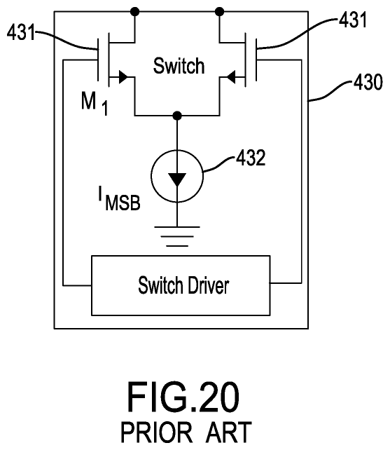

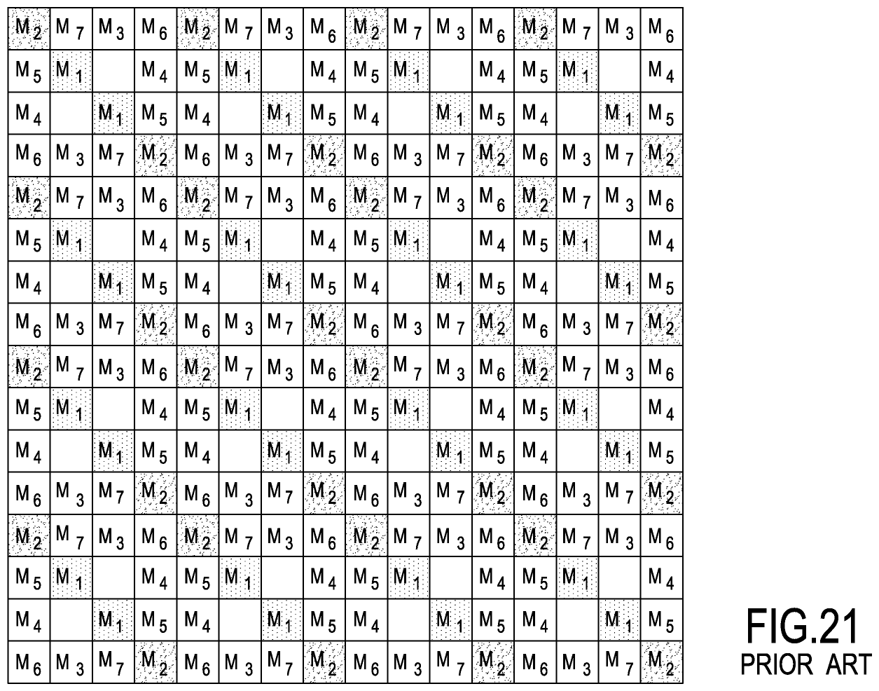

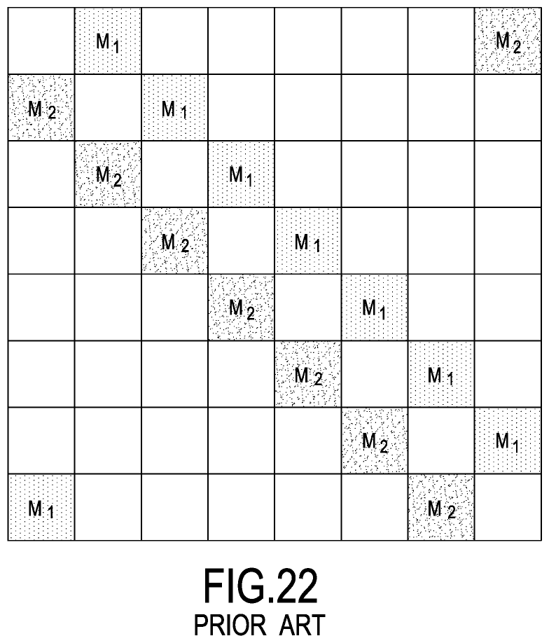

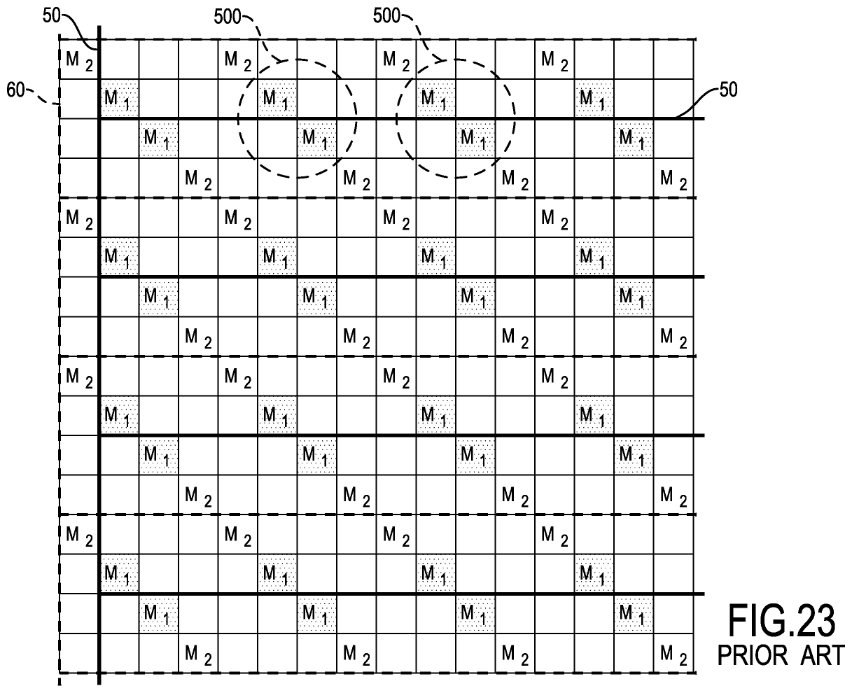

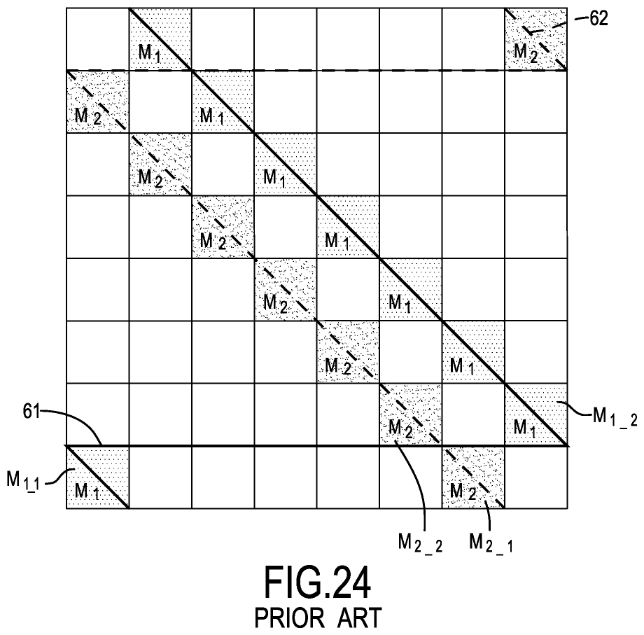

The symmetrical layout structure 10 of the present invention can be applied to a digital-to-analog converter (hereinafter referenced as DAC). The basic introduction to the current steering DAC is disclosed in DESCRIPTION OF RELATED ART mentioned above. In the DAC, the working unit is a current cell, the sub-working unit is a sub-current cell, and the dummy unit is a dummy cell. Accordingly, the symmetrical layout structure 10 is performed in a (2^{M+1})×(2^{M+1}) current cell array. In brief, the current steering DAC comprises a decoder, a switch driver and the current cell array. As illustrated in FIG. 20, each sub-current cell can be composed of two electric switches (such as MOSFETs) and current sources. For example, the two electric switches can be named as a first electric switch and a second electric switch. In a same current cell, the gates of the first electric switches are electrically connected by a driving wire, and the gates of the second electric switches are electrically connected by another driving wire. Hence, the sub-current cells of a same current cell are electrically connected in parallel.

The decoder has M input terminals for receiving an M-bit digital signal, wherein M represents the resolution of the current steering DAC. After the decoder decodes the digital signal, a decoding result is transmitted to the switch driver. The switch driver sends driving signals to activate the current cells according to the decoding result. The current cell array outputs an analog signal obtained from the current cells.

In the present invention, the symmetrical layout structure 10 of the DAC is described as follows. For example, r can be 1. The symmetrical layout structure 10 comprises 2^{M}−1 current cells and one dummy unit. The dummy unit has 2^{2+M} dummy elements. Each current cell has 2^{2+M} sub-current cells continuously connected by a closed trace and arranged along the closed trace. The closed trace is symmetrical to a diagonal path of the current cell array. The placement of the sub-current cells in each current cell forms a parallelogram, and the mismatch of each side is used to compensate the mismatch of the opposite side. Since all parallelograms have the same centroid, the currents from the current cells are similar to each other. Moreover, the perimeters of all parallelograms are the same, and so the lengths of the closed traces of the current cells are the same. Further, the distance between all sub-current cells are the same. Compared with the conventional layout structure, the present invention has better performance in overcoming timing skew effect, and can improve the performance of the digital-to-analog converter.

### Embodiment 1

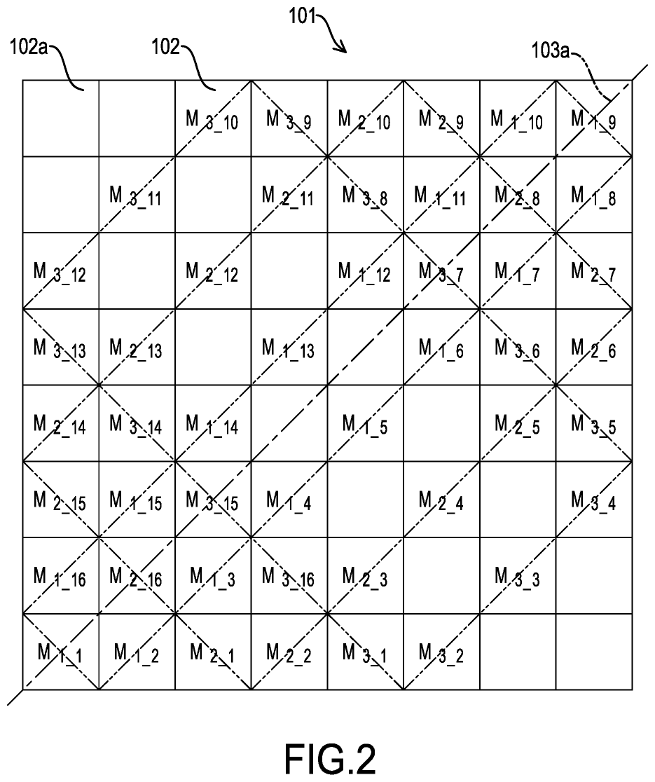

The DAC is a 2-bit DAC. With reference to FIGS. 2 and 3, the symmetrical layout structure 101 is performed in an 8×8 (calculated from 2²⁺¹×2²⁺¹) current cell array. The symmetrical layout structure 101 comprises three (calculated from 2²−1) current cells respectively named as M1, M2 and M3 and one dummy cell. The dummy cell has 16 (calculated from 2²⁺²) dummy elements 102a. Each current cells has 16 (calculated from 2²⁺²) sub-current cells 102 arranged as a closed trace that is symmetrical to the diagonal path 103a of the current cell array. The diagonal path 103a goes through the sub-current cells located at the positions (1, 8) and (8, 1). When the current of the current cell is I, the current of each sub-current cell is I/16

In detail, a first current cell M1 has 16 sub-current cells 102 respectively named as M_{1_1}, M_{1_2} to M_{1_16}. A second current cell M2 has 16 sub-current cells 102 respectively named as M_{2_1}, M_{2_2} to M_{2_16}. A third current cell M3 has 16 sub-current cells 102 respectively named as M_{3_1}, M_{3_2} to M_{3_16}. The following table discloses an example of the positions of the sub-current cells 102 of the current cells M1, M2 and M3.

| sub-current cell | position |
|---|---|
| M₁_{_{—}}₁ | (8, 1) |
| M₁_{_{—}}₂ | (8, 2) |
| M₁_{_{—}}₃ | (7, 3) |
| M₁_{_{—}}₄ | (6, 4) |
| M₁_{_{—}}₅ | (5, 5) |
| M₁_{_{—}}₆ | (4, 6) |
| M₁_{_{—}}₇ | (3, 7) |
| M₁_{_{—}}₈ | (2, 8) |
| M₁_{_{—}}₉ | (1, 8) |
| M₁_{_{—}}₁₀ | (1, 7) |
| M₁_{_{—}}₁₁ | (2, 6) |
| M₁_{_{—}}₁₂ | (3, 5) |
| M₁_{_{—}}₁₃ | (4, 4) |
| M₁_{_{—}}₁₄ | (5, 3) |
| M₁_{_{—}}₁₅ | (6, 2) |
| M₁_{_{—}}₁₆ | (7, 1) |
| M₂_{_{—}}₁ | (8, 3) |
| M₂_{_{—}}₂ | (8, 4) |
| M₂_{_{—}}₃ | (7, 5) |
| M₂_{_{—}}₄ | (6, 6) |
| M₂_{_{—}}₅ | (5, 7) |
| M₂_{_{—}}₆ | (4, 8) |
| M₂_{_{—}}₇ | (3, 8) |
| M₂_{_{—}}₈ | (2, 7) |
| M₂_{_{—}}₉ | (1, 6) |
| M₂_{_{—}}₁₀ | (1, 5) |
| M₂_{_{—}}₁₁ | (2, 4) |
| M₂_{_{—}}₁₂ | (3, 3) |
| M₂_{_{—}}₁₃ | (4, 2) |
| M₂_{_{—}}₁₄ | (5, 1) |
| M₂_{_{—}}₁₅ | (6, 1) |
| M₂_{_{—}}₁₆ | (7, 2) |
| M₃_{_{—}}₁ | (8, 5) |
| M₃_{_{—}}₂ | (8, 6) |
| M₃_{_{—}}₃ | (7, 7) |
| M₃_{_{—}}₄ | (6, 8) |
| M₃_{_{—}}₅ | (5, 8) |
| M₃_{_{—}}₆ | (4, 7) |
| M₃_{_{—}}₇ | (3, 6) |
| M₃_{_{—}}₈ | (2, 5) |
| M₃_{_{—}}₉ | (1, 4) |
| M₃_{_{—}}₁₀ | (1, 3) |
| M₃_{_{—}}₁₁ | (2, 2) |
| M₃_{_{—}}₁₂ | (3, 1) |
| M₃_{_{—}}₁₃ | (4, 1) |
| M₃_{_{—}}₁₄ | (5, 2) |
| M₃_{_{—}}₁₅ | (6, 3) |
| M₃_{_{—}}₁₆ | (7, 4) |

Please note that the positions of the sub-current cells of each current cell M1-M3 are changeable and are not limited to positions as disclosed in the above table. Regarding FIG. 2, in other words, the dummy elements 102a can be interchanged with the sub-current cells 102 of any one of the current cells M1-M3.

The placement of the sub-current cells of each current cell forms a parallelogram, and the mismatch of each side is used to compensate the mismatch of the opposite side. Taking the current cell M1 as an example, the sub-current cell M_{1_1} is used to compensate the sub-current cell M_{1_9}, and the sub-current cells M_{1_2}-M_{1_8} are respectively used to compensate the sub-current cells M_{1_10}-M_{1_16}. As a whole, the analog signal outputted from the current cell array 101 is homogeneous.

According to FIG. 2, taking the first current cell M1 and second current cell M2 as examples, with reference to FIG. 3, the sub-current cells M_{1_1}-M_{1_16} are connected by the closed trace 103 as a driving wire, and the sub-current cells M_{2_1}-M_{2_16} are connected by the closed trace 104 as a driving wire. The perimeters of the parallelogram formed by the sub-current cells M_{1_1}-M_{1_16} and the perimeters of the parallelogram formed by the sub-current cells M_{2_1}-M_{2_16} are the same, and so the length of the closed trace 103 is the same as the length of the closed trace 104. Further, the distance between the sub-current cells M_{1_1}-M_{1_16} and the distance between the sub-current cells M_{2_1}-M_{2_16} are the same. Therefore, the sub-current cells M_{1_1}-M_{1_16} are activated similar to the sub current cells M_{2_1}-M_{2_16}. The timing skew defect is thus overcome.

The same result in the third current cell M3 can be deduced by analogy based on the first current cell M1 and second current cell M2.

### Embodiment 2

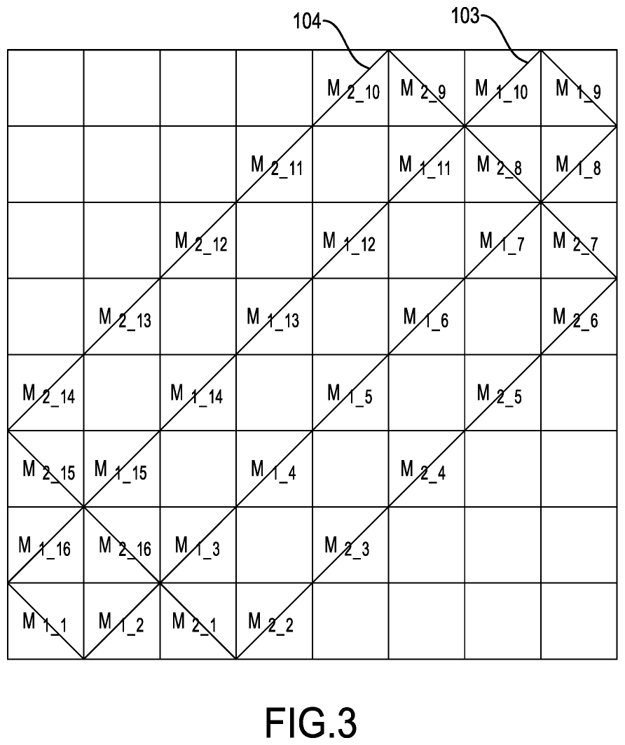

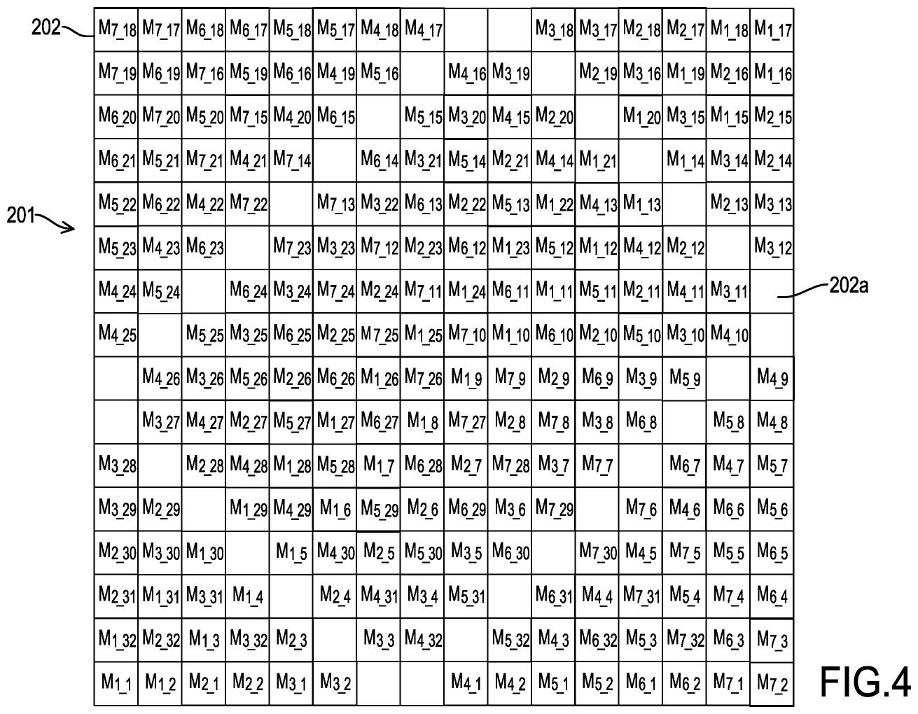

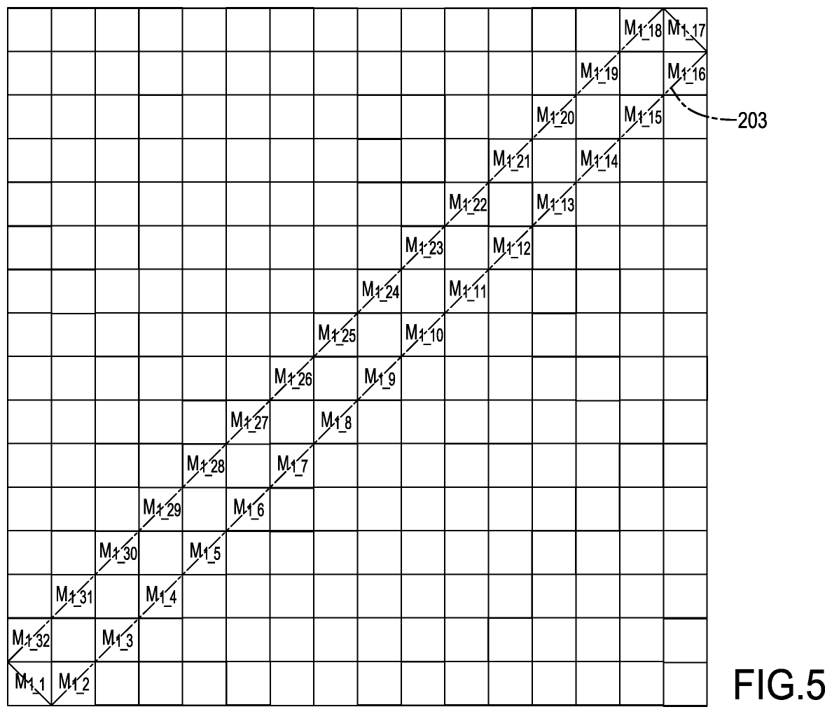

The DAC is a 3-bit DAC. With reference to FIG. 4, the symmetrical layout structure 201 is performed in a 16×16 (calculated from 2³⁺¹×2³⁺¹) current cell array, and comprises seven (calculated from 2³−1) current cells respectively named as M1, M2 to M7 and one dummy cell. The dummy cell has 32 (calculated from 2³⁺²) dummy elements 202a. Each current cell has 32 (calculated from 2³⁺²) sub-current cells 202 arranged as a closed trace symmetrical to the diagonal path of the current cell array. The diagonal path goes through the sub-current cells located at the positions (1, 16) and (16, 1). In detail, a first current cell M1 has 32 sub-current cells respectively named as M_{1_1}, M_{1_2} to M_{1_32}. The following table and FIG. 5 disclose an example of the positions of the sub-current cells of the first current cell M1.

| sub-current cell | Position | sub-current cell | position |
|---|---|---|---|
| M₁_{_{—}}₁ | (16, 1) | M₁_{_{—}}₁₇ | (1, 16) |
| M₁_{_{—}}₂ | (16, 2) | M₁_{_{—}}₁₈ | (1, 15) |
| M₁_{_{—}}₃ | (15, 3) | M₁_{_{—}}₁₉ | (2, 14) |
| M₁_{_{—}}₄ | (14, 4) | M₁_{_{—}}₂₀ | (3, 13) |
| M₁_{_{—}}₅ | (13, 5) | M₁_{_{—}}₂₁ | (4, 12) |
| M₁_{_{—}}₆ | (12, 6) | M₁_{_{—}}₂₂ | (5, 11) |
| M₁_{_{—}}₇ | (11, 7) | M₁_{_{—}}₂₃ | (6, 10) |
| M₁_{_{—}}₈ | (10, 8) | M₁_{_{—}}₂₄ | (7, 9) |
| M₁_{_{—}}₉ | (9, 9) | M₁_{_{—}}₂₅ | (8, 8) |
| M₁_{_{—}}₁₀ | (8, 10) | M₁_{_{—}}₂₆ | (9, 7) |
| M₁_{_{—}}₁₁ | (7, 11) | M₁_{_{—}}₂₇ | (10, 6) |
| M₁_{_{—}}₁₂ | (6, 12) | M₁_{_{—}}₂₈ | (11, 5) |
| M₁_{_{—}}₁₃ | (5, 13) | M₁_{_{—}}₂₉ | (12, 4) |
| M₁_{_{—}}₁₄ | (4, 14) | M₁_{_{—}}₃₀ | (13, 3) |
| M₁_{_{—}}₁₅ | (3, 15) | M₁_{_{—}}₃₁ | (14, 2) |
| M₁_{_{—}}₁₆ | (2, 16) | M₁_{_{—}}₃₂ | (15, 1) |

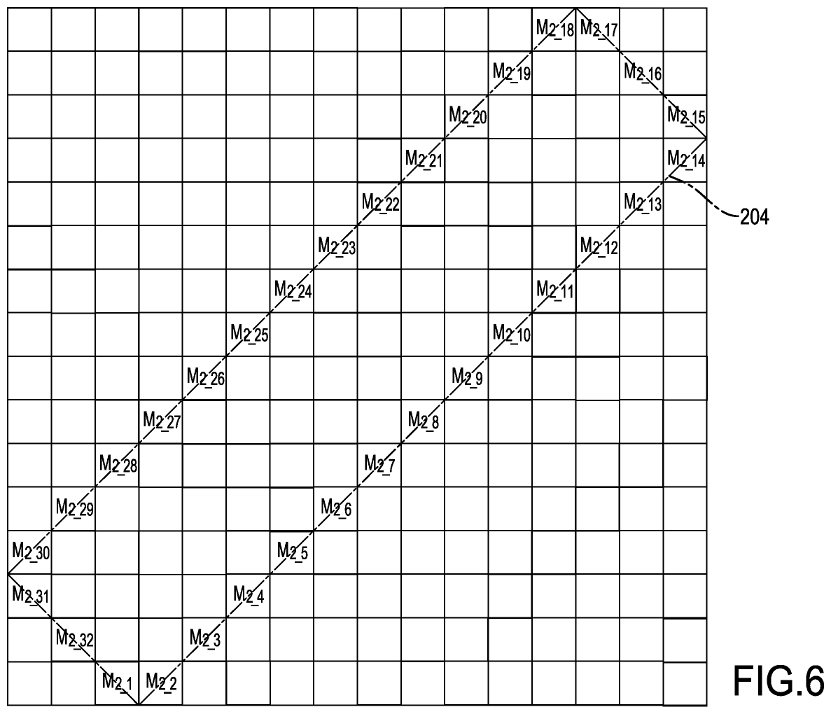

A second current cell M2 has 32 sub-current cells respectively named as M_{2_1}, M_{2_2} to M_{2_32}. The following table and FIG. 6 disclose an example of the positions of the sub-current cells in the second current cell M2.

| sub-current cell | position |
|---|---|
| M₂_{_{—}}₁ | (16, 3) |
| M₂_{_{—}}₂ | (16, 4) |
| M₂_{_{—}}₃ | (15, 5) |
| M₂_{_{—}}₄ | (14, 6) |
| M₂_{_{—}}₅ | (13, 7) |
| M₂_{_{—}}₆ | (12, 8) |
| M₂_{_{—}}₇ | (11, 9) |
| M₂_{_{—}}₈ | (10, 10) |
| M₂_{_{—}}₉ | (9, 11) |
| M₂_{_{—}}₁₀ | (8, 12) |
| M₂_{_{—}}₁₁ | (7, 13) |
| M₂_{_{—}}₁₂ | (6, 14) |
| M₂_{_{—}}₁₃ | (5, 15) |
| M₂_{_{—}}₁₄ | (4, 16) |
| M₂_{_{—}}₁₅ | (3, 16) |
| M₂_{_{—}}₁₆ | (2, 15) |
| M₂_{_{—}}₁₇ | (1, 14) |
| M₂_{_{—}}₁₈ | (1, 13) |
| M₂_{_{—}}₁₉ | (2, 12) |
| M₂_{_{—}}₂₀ | (3, 11) |
| M₂_{_{—}}₂₁ | (4, 10) |
| M₂_{_{—}}₂₂ | (5, 9) |
| M₂_{_{—}}₂₃ | (6, 8) |
| M₂_{_{—}}₂₄ | (7, 7) |
| M₂_{_{—}}₂₅ | (8, 6) |
| M₂_{_{—}}₂₆ | (9, 5) |
| M₂_{_{—}}₂₇ | (10, 4) |
| M₂_{_{—}}₂₈ | (11, 3) |
| M₂_{_{—}}₂₉ | (12, 2) |
| M₂_{_{—}}₃₀ | (13, 1) |
| M₂_{_{—}}₃₁ | (14, 1) |
| M₂_{_{—}}₃₂ | (15, 2) |

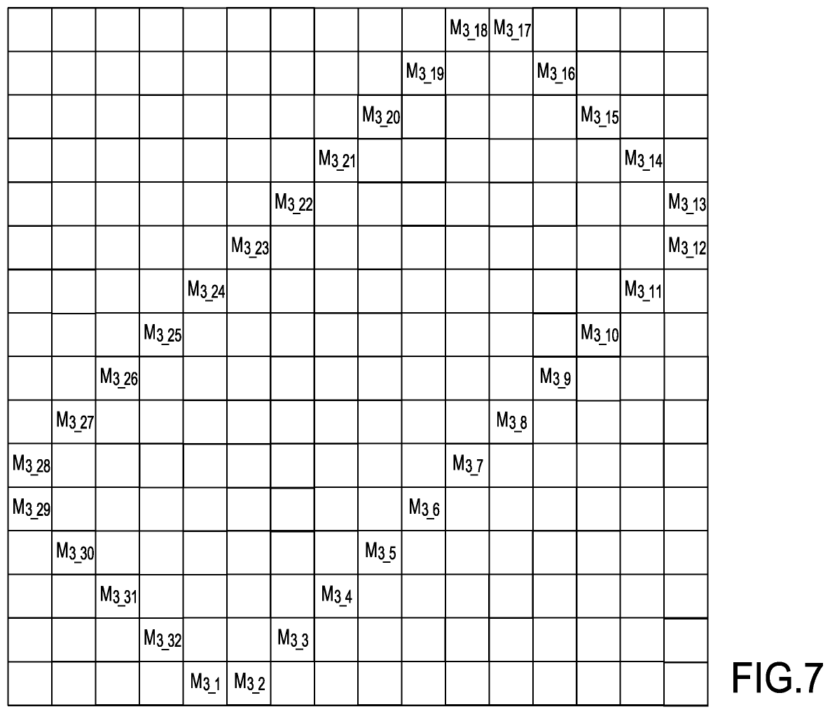

A third current cell M3 has 32 sub-current cells respectively named as M_{3_1}, M_{3_2} to M_{3_32}. The following table and FIG. 7 disclose an example of the positions of the sub-current cells in the third current cell M3.

| sub-current cell | position |
|---|---|
| M₃_{_{—}}₁ | (16, 5) |
| M₃_{_{—}}₂ | (16, 6) |
| M₃_{_{—}}₃ | (15, 7) |
| M₃_{_{—}}₄ | (14, 8) |
| M₃_{_{—}}₅ | (13, 9) |
| M₃_{_{—}}₆ | (12, 10) |
| M₃_{_{—}}₇ | (11, 11) |
| M₃_{_{—}}₈ | (10, 12) |
| M₃_{_{—}}₉ | (9, 13) |
| M₃_{_{—}}₁₀ | (8, 14) |
| M₃_{_{—}}₁₁ | (7, 15) |
| M₃_{_{—}}₁₂ | (6, 16) |
| M₃_{_{—}}₁₃ | (5, 16) |
| M₃_{_{—}}₁₄ | (4, 15) |
| M₃_{_{—}}₁₅ | (3, 14) |
| M₃_{_{—}}₁₆ | (2, 13) |
| M₃_{_{—}}₁₇ | (1, 12) |
| M₃_{_{—}}₁₈ | (1, 11) |
| M₃_{_{—}}₁₉ | (2, 10) |
| M₃_{_{—}}₂₀ | (3, 9) |
| M₃_{_{—}}₂₁ | (4, 8) |
| M₃_{_{—}}₂₂ | (5, 7) |
| M₃_{_{—}}₂₃ | (6, 6) |
| M₃_{_{—}}₂₄ | (7, 5) |
| M₃_{_{—}}₂₅ | (8, 4) |
| M₃_{_{—}}₂₆ | (9, 3) |
| M₃_{_{—}}₂₇ | (10, 2) |
| M₃_{_{—}}₂₈ | (11, 1) |
| M₃_{_{—}}₂₉ | (12, 1) |
| M₃_{_{—}}₃₀ | (13, 2) |
| M₃_{_{—}}₃₁ | (14, 3) |
| M₃_{_{—}}₃₂ | (15, 4) |

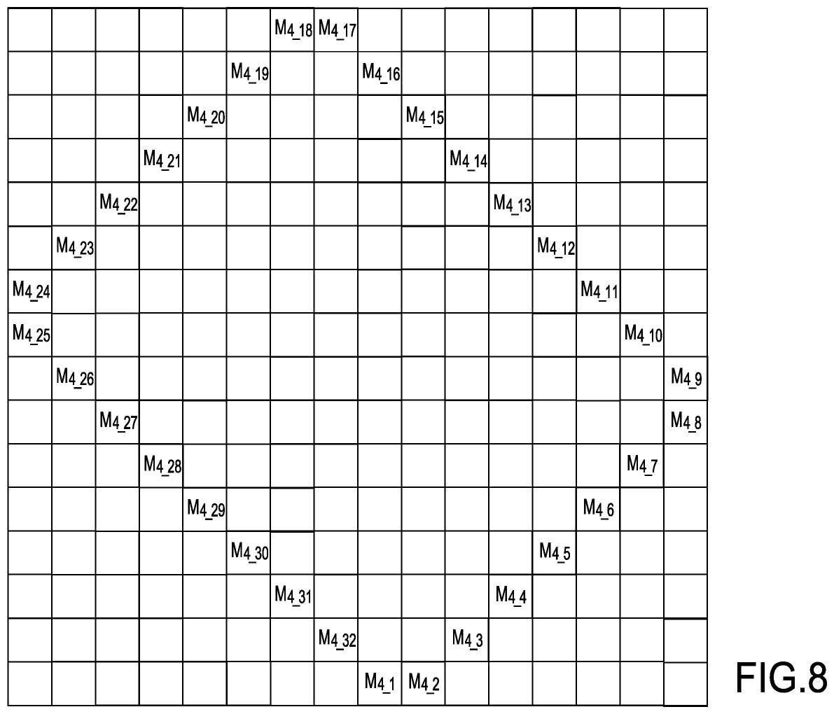

A fourth current cell M4 has 32 sub-current cells respectively named as M_{4_1}, M_{4_2} to M_{4_32}. The following table and FIG. 8 disclose an example of the positions of the sub-current cells in the fourth current cell M4.

| sub-current cell | position |
|---|---|
| M₄_{_{—}}₁ | (16, 9) |
| M₄_{_{—}}₂ | (16, 10) |
| M₄_{_{—}}₃ | (15, 11) |
| M₄_{_{—}}₄ | (14, 12) |
| M₄_{_{—}}₅ | (13, 13) |
| M₄_{_{—}}₆ | (12, 14) |
| M₄_{_{—}}₇ | (11, 15) |
| M₄_{_{—}}₈ | (10, 16) |
| M₄_{_{—}}₉ | (9, 16) |
| M₄_{_{—}}₁₀ | (8, 15) |
| M₄_{_{—}}₁₁ | (7, 14) |
| M₄_{_{—}}₁₂ | (6, 13) |
| M₄_{_{—}}₁₃ | (5, 12) |
| M₄_{_{—}}₁₄ | (4, 11) |
| M₄_{_{—}}₁₅ | (3, 10) |
| M₄_{_{—}}₁₆ | (2, 9) |
| M₄_{_{—}}₁₇ | (1, 8) |
| M₄_{_{—}}₁₈ | (1, 7) |
| M₄_{_{—}}₁₉ | (2, 6) |
| M₄_{_{—}}₂₀ | (3, 5) |
| M₄_{_{—}}₂₁ | (4, 4) |
| M₄_{_{—}}₂₂ | (5, 3) |
| M₄_{_{—}}₂₃ | (6, 2) |
| M₄_{_{—}}₂₄ | (7, 1) |
| M₄_{_{—}}₂₅ | (8, 1) |
| M₄_{_{—}}₂₆ | (9, 2) |
| M₄_{_{—}}₂₇ | (10, 3) |
| M₄_{_{—}}₂₈ | (11, 4) |
| M₄_{_{—}}₂₉ | (12, 5) |
| M₄_{_{—}}₃₀ | (13, 6) |
| M₄_{_{—}}₃₁ | (14, 7) |
| M₄_{_{—}}₃₂ | (15, 8) |

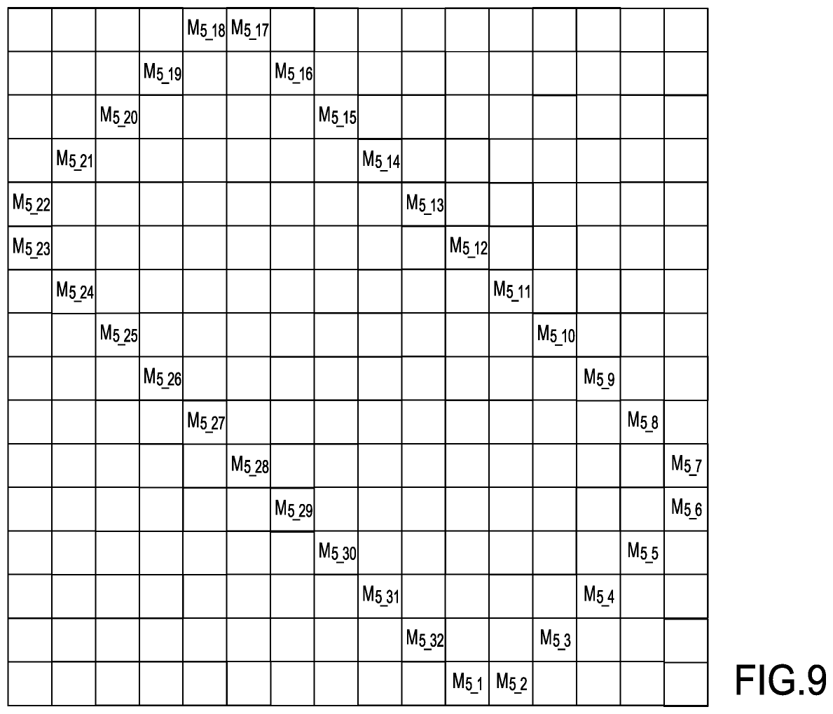

A fifth current cell M5 has 32 sub-current cells respectively named as M_{5_1}, M_{5_2} to M_{5_32}. The following table and FIG. 9 disclose an example of the positions of the sub-current cells in the fifth current cell M5.

| sub-current cell | position |
|---|---|
| M₅_{_{—}}₁ | (16, 11) |
| M₅_{_{—}}₂ | (16, 12) |
| M₅_{_{—}}₃ | (15, 13) |
| M₅_{_{—}}₄ | (14, 14) |
| M₅_{_{—}}₅ | (13, 15) |
| M₅_{_{—}}₆ | (12, 16) |
| M₅_{_{—}}₇ | (11, 16) |
| M₅_{_{—}}₈ | (10, 15) |
| M₅_{_{—}}₉ | (9, 14) |
| M₅_{_{—}}₁₀ | (8, 13) |
| M₅_{_{—}}₁₁ | (7, 12) |
| M₅_{_{—}}₁₂ | (6, 11) |
| M₅_{_{—}}₁₃ | (5, 10) |
| M₅_{_{—}}₁₄ | (4, 9) |
| M₅_{_{—}}₁₅ | (3, 8) |
| M₅_{_{—}}₁₆ | (2, 7) |
| M₅_{_{—}}₁₇ | (1, 6) |
| M₅_{_{—}}₁₈ | (1, 5) |
| M₅_{_{—}}₁₉ | (2, 4) |
| M₅_{_{—}}₂₀ | (3, 3) |
| M₅_{_{—}}₂₁ | (4, 2) |
| M₅_{_{—}}₂₂ | (5, 1) |
| M₅_{_{—}}₂₃ | (6, 1) |
| M₅_{_{—}}₂₄ | (7, 2) |
| M₅_{_{—}}₂₅ | (8, 3) |
| M₅_{_{—}}₂₆ | (9, 4) |
| M₅_{_{—}}₂₇ | (10, 5) |
| M₅_{_{—}}₂₈ | (11, 6) |
| M₅_{_{—}}₂₉ | (12, 7) |
| M₅_{_{—}}₃₀ | (13, 8) |
| M₅_{_{—}}₃₁ | (14, 9) |
| M₅_{_{—}}₃₂ | (15, 10) |

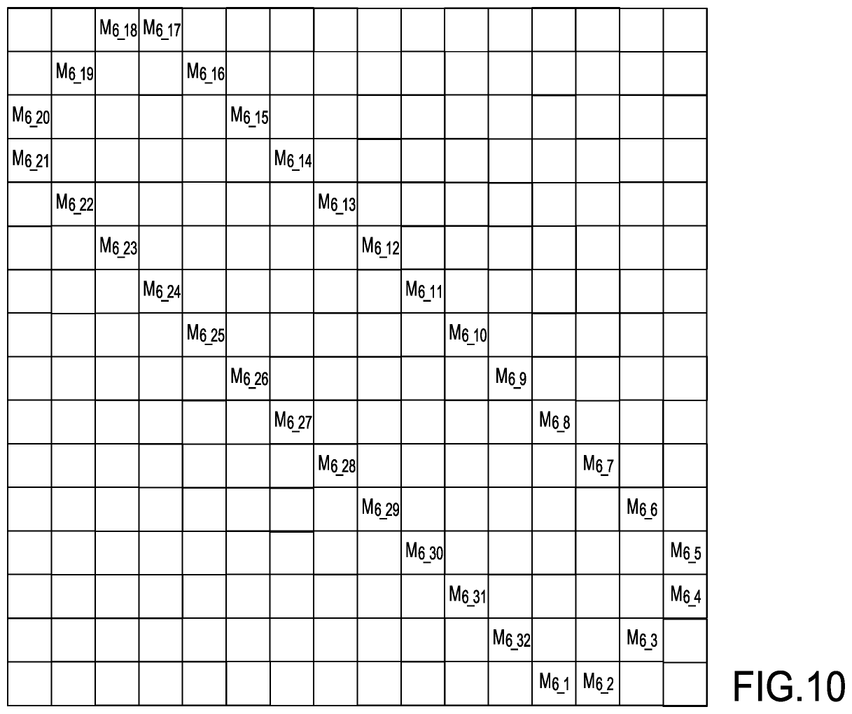

A sixth current cell M6 has 32 sub-current cells respectively named as M_{6_1}, M_{6_2} to M_{6_32}. The following table and FIG. 10 disclose an example of the positions of the sub-current cells in the sixth current cell M6.

| sub-current cell | position |
|---|---|
| M₆_{_{—}}₁ | (16, 13) |
| M₆_{_{—}}₂ | (16, 14) |
| M₆_{_{—}}₃ | (15, 15) |
| M₆_{_{—}}₄ | (14, 16) |
| M₆_{_{—}}₅ | (13, 16) |
| M₆_{_{—}}₆ | (12, 15) |
| M₆_{_{—}}₇ | (11, 14) |
| M₆_{_{—}}₈ | (10, 13) |
| M₆_{_{—}}₉ | (9, 12) |
| M₆_{_{—}}₁₀ | (8, 11) |
| M₆_{_{—}}₁₁ | (7, 10) |
| M₆_{_{—}}₁₂ | (6, 9) |
| M₆_{_{—}}₁₃ | (5, 8) |
| M₆_{_{—}}₁₄ | (4, 7) |
| M₆_{_{—}}₁₅ | (3, 6) |
| M₆_{_{—}}₁₆ | (2, 5) |
| M₆_{_{—}}₁₇ | (1, 4) |
| M₆_{_{—}}₁₈ | (1, 3) |
| M₆_{_{—}}₁₉ | (2, 2) |
| M₆_{_{—}}₂₀ | (3, 1) |
| M₆_{_{—}}₂₁ | (4, 1) |
| M₆_{_{—}}₂₂ | (5, 2) |
| M₆_{_{—}}₂₃ | (6, 3) |
| M₆_{_{—}}₂₄ | (7, 4) |
| M₆_{_{—}}₂₅ | (8, 5) |
| M₆_{_{—}}₂₆ | (9, 6) |
| M₆_{_{—}}₂₇ | (10, 7) |
| M₆_{_{—}}₂₈ | (11, 8) |
| M₆_{_{—}}₂₉ | (12, 9) |
| M₆_{_{—}}₃₀ | (13, 10) |
| M₆_{_{—}}₃₁ | (14, 11) |
| M₆_{_{—}}₃₂ | (15, 12) |

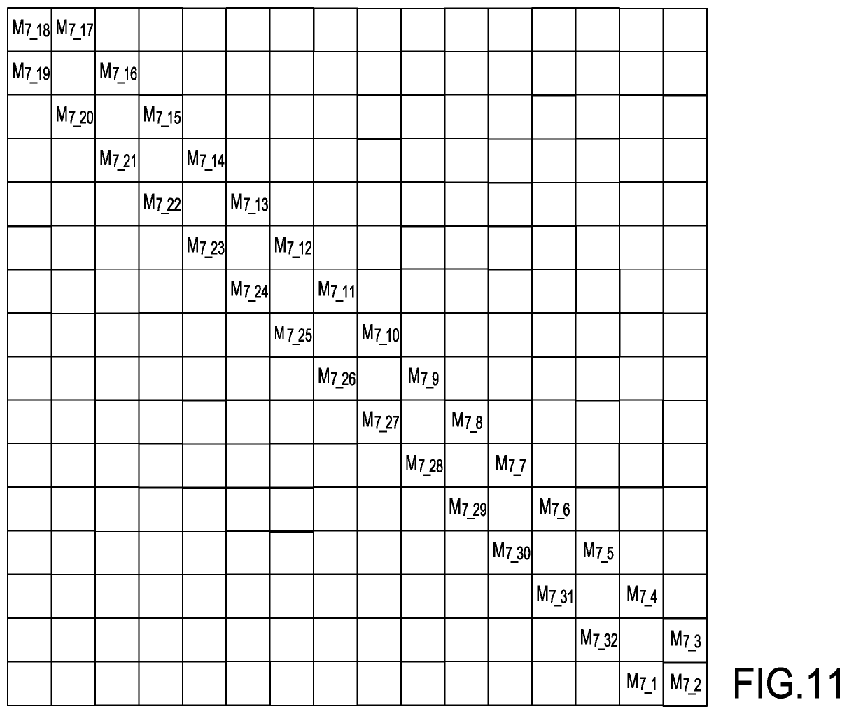

A seventh current cell M7 has 32 sub-current cells respectively named as M_{7_1}, M_{7_2} to M_{7_32}. The following table and FIG. 11 disclose an example of the positions of the sub-current cells in the seventh current cell M7.

| sub-current cell | position |
|---|---|
| M₇_{_{—}}₁ | (16, 15) |
| M₇_{_{—}}₂ | (16, 16) |
| M₇_{_{—}}₃ | (15, 16) |
| M₇_{_{—}}₄ | (14, 15) |
| M₇_{_{—}}₅ | (13, 14) |
| M₇_{_{—}}₆ | (12, 13) |
| M₇_{_{—}}₇ | (11, 12) |
| M₇_{_{—}}₈ | (10, 11) |
| M₇_{_{—}}₉ | (9, 10) |
| M₇_{_{—}}₁₀ | (8, 9) |
| M₇_{_{—}}₁₁ | (7, 8) |
| m₇_{_{—}}₁₂ | (6, 7) |
| M₇_{_{—}}₁₃ | (5, 6) |
| M₇_{_{—}}₁₄ | (4, 5) |
| M₇_{_{—}}₁₅ | (3, 4) |
| M₇_{_{—}}₁₆ | (2, 3) |
| M₇_{_{—}}₁₇ | (1, 2) |
| M₇_{_{—}}₁₈ | (1, 1) |
| M₇_{_{—}}₁₉ | (2, 1) |
| M₇_{_{—}}₂₀ | (3, 2) |
| M₇_{_{—}}₂₁ | (4, 3) |
| M₇_{_{—}}₂₂ | (5, 4) |
| M₇_{_{—}}₂₃ | (6, 5) |
| M₇_{_{—}}₂₄ | (7, 6) |
| M₇_{_{—}}₂₅ | (8, 7) |
| M₇_{_{—}}₂₆ | (9, 8) |
| M₇_{_{—}}₂₇ | (10, 9) |
| M₇_{_{—}}₂₈ | (11, 10) |
| M₇_{_{—}}₂₉ | (12, 11) |
| M₇_{_{—}}₃₀ | (13, 12) |
| M₇_{_{—}}₃₁ | (14, 13) |
| M₇_{_{—}}₃₂ | (15, 14) |

Please note that the positions of the sub-current cells 202 of each current cell M1-M7 are changeable and are not limited to positions as disclosed in the above tables. Regarding FIG. 4, in other words, the dummy elements 202a can be interchanged with the sub-current cells 202 of any one of the current cells M1-M7.

Taking the first current cell M1 and second current cell M2 as an example, with reference to FIG. 5 and FIG. 6, the sub current cells M_{1_1}- M_{1_32} in the current cell M1 are electrically connected by a closed trace 203 as a driving wire, and the sub-current cells M_{2_1}-M_{2_32} in the current cell M2 are electrically connected by a closed trace 204. The placement of the sub-current cells in each current cell forms a parallelogram, and the mismatch of each side is used to compensate the mismatch of the opposite side. Taking the current cell M1 as an example, the sub-current cell M_{1_1} is used to compensate the sub-current cell M_{1_17}, and the sub-current cells M_{1_2}-M_{1_16} are respectively used to compensate the sub-current cells M_{1_18}-M_{1_32}. As a whole, the analog signal outputted from the current cell array 201 is homogeneous. The perimeters of the parallelogram formed by the sub-current cells M_{1_1}-M_{1_32} and the perimeters of the parallelogram formed by the sub-current cells M_{2_1}-M_{2_32} are the same, and so the length of the closed trace 203 disclosed in FIG. 5 is the same as the length of the closed trace 204 disclosed in FIG. 6. Further, the distance between the sub-current cells M_{1_1}-M_{1_32} and the distance between the sub-current cells M_{2_1}-M_{2_32} are the same. Therefore, the sub-current cells M_{1_1}-M_{1_32} are activated similar to the sub-current cells M_{2_1}-M_{2_32}. The timing skew defect is therefore thus overcome. Accordingly, the same result in the current cells M3-M7 can be deduced by analogy based on the current cells M1, M2.

### Embodiment 3

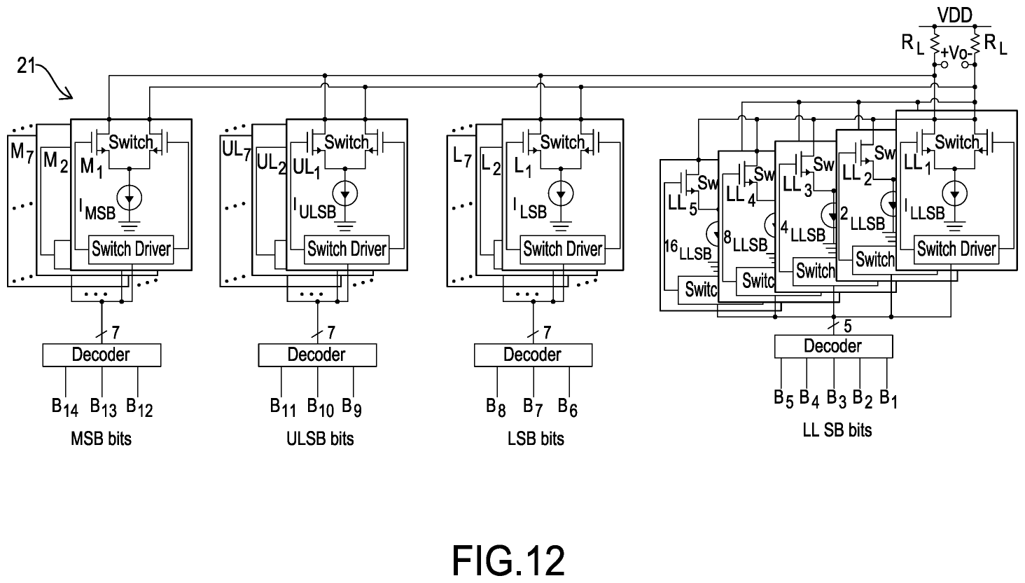

In a segmented DAC, input bits are divided into multiple bit groups is common knowledge. For example, with reference to FIG. 12, a 14-bit segmented DAC is divided into 3 most significant bits (MSB), 3 upper least significant bits (ULSB), 3 least significant bits (LSB) and 4 lower least significant bits (LLSB). MSB and ULSB have most influential relationship to affect the DAC performance. The bit group of MSB is performed by a current cell array 21. Because the bit group of MSB has 3-bit inputs, the layout structure of MSB is referred to EMBODIMENT 2. Further, the bit group ULSB is composed of 7 (calculated from 2³−1) current cells respectively named as U1-U7. Each current cell has 4 sub-current cells. For example, the sub-current cells of the current cell U1 are named respectively as U_{1_1}, U_{1_2}, U_{1_3} and U_{1_4}.

The following table discloses the positions of the sub-current cells in the current cells U1-U7. The placement of the bit group ULSB is akin to the placement of the bit group MSB. Therefore, mismatch error compensation within the bit group ULSB is also achieved. With the invention, the MSB to ULSB current ratio is close to 8, which means the mismatch error between the bit groups MSB and ULSB are suppressed.

| sub-current cell | position | sub-current cell | Position | sub-current cell | position |
|---|---|---|---|---|---|
| U₁_{_{—}}₁ | (14, 5) | U₄_{_{—}}₁ | (16, 8) | U₇_{_{—}}₁ | (13, 11) |
| U₁_{_{—}}₂ | (5, 14) | U₄_{_{—}}₂ | (8, 16) | U₇_{_{—}}₂ | (11, 13) |
| U₁_{_{—}}₃ | (3, 12) | U₄_{_{—}}₃ | (1, 9) | U₇_{_{—}}₃ | (4, 6) |
| U₁_{_{—}}₄ | (12, 3) | U₄_{_{—}}₄ | (9, 1) | U₇_{_{—}}₄ | (6, 4) |

| | | | |
|---|---|---|---|
| U₂_{_{—}}₁ | (15, 6) | U₅_{_{—}}₁ | (15, 9) |
| U₂_{_{—}}₂ | (6, 15) | U₅_{_{—}}₂ | (9, 15) |
| U₂_{_{—}}₃ | (2, 11) | U₅_{_{—}}₃ | (2, 8) |
| U₂_{_{—}}₄ | (11, 2) | U₅_{_{—}}₄ | (8, 2) |
| U₃_{_{—}}₁ | (16, 7) | U₆_{_{—}}₁ | (14, 10) |
| U₃_{_{—}}₂ | (7, 16) | U₆_{_{—}}₂ | (10, 14) |
| U₃_{_{—}}₃ | (1, 10) | U₆_{_{—}}₃ | (3, 7) |
| U₃_{_{—}}₄ | (10, 1) | U₆_{_{—}}₄ | (7, 3) |

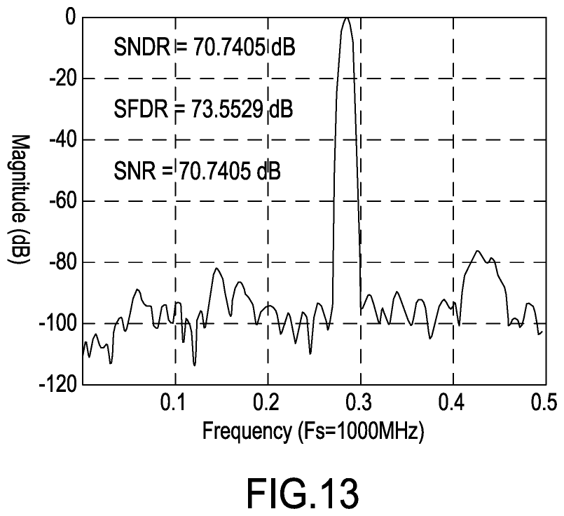

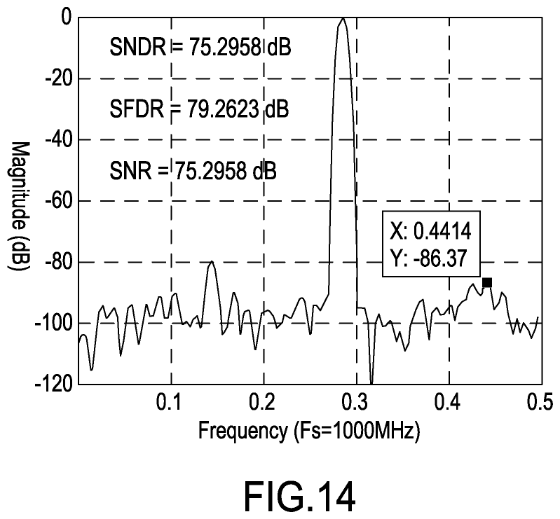

In conclusion, according to experimental result, compared with the first and the second conventional layout structures, the time delay of the first conventional layout structure is 0.8701 pico-second between different current cells, the time delay of the second conventional layout structure is 0.7973 pico-second between different current cells, and the time delay of the present invention is almost 0 pico-second between different current cells. The present invention doubtlessly has better performance in timely transmitting the driving signal. Besides, SNDR (Signal-to-noise and distortion ratio), SFDR (Spurious-Free Dynamic Range) and SNR (Signal to Noise Ratio) are factors to determine the performance of a DAC. With reference to FIGS. 13 and 14, FIG. 13 is a simulating result of the second conventional layout structure and FIG. 14 is a simulating result of the present invention. Obviously, the SNDR, SFDR and SNR performances of the present invention are better than those of the second conventional layout structure.

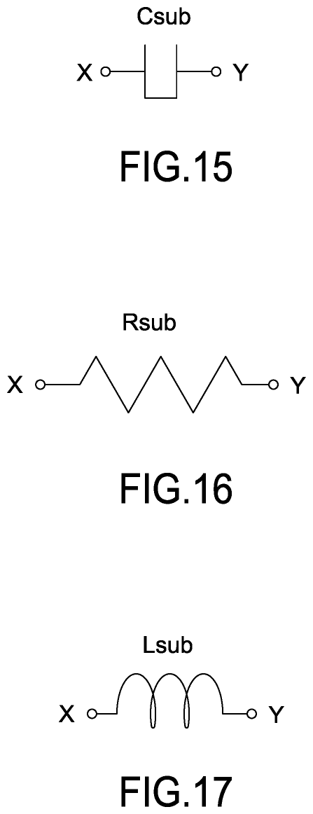

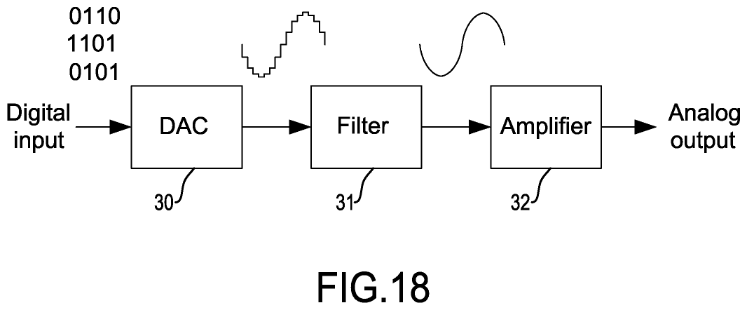

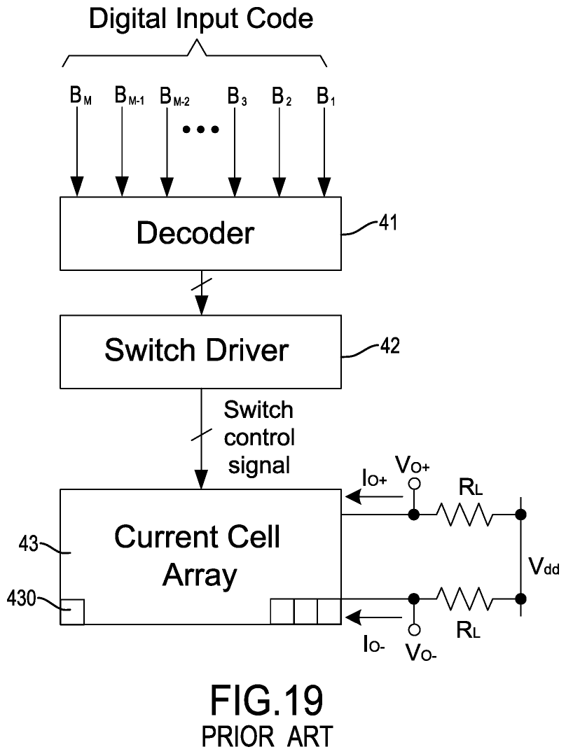

The symmetrical layout structure of the present invention is not limited to be applied to DAC as mentioned above. In another embodiment, the symmetrical layout structure can be performed in a capacitor array, such that the working unit can be a capacitor unit, and the sub-working unit can be a sub-capacitor unit. With reference to FIG. 15, the sub-capacitor unit C_{sub} has a first terminal X and a second terminal Y. For a parallel connection, the first terminals X of the sub-capacitor units C_{sub} in a same capacitor unit are electrically connected by a driving wire, and the second terminals Y of the sub-capacitor units C_{sub} in a same capacitor unit are electrically connected by another driving wire. For example, the capacitor unit has n sub-capacitor units. When the capacitance of one capacitor unit is C, the capacitance of each sub-capacitor unit is C/n. For a series connection, regarding two adjacent sub-capacitor units C_{sub} in a same capacitor unit, the first terminal X of one sub-capacitor unit C_{sub} is electrically connected to the second terminal Y of another sub-capacitor unit C_{sub} by a driving wire. For example, the capacitor unit has n sub-capacitor units. When the capacitance of one capacitor unit is C, the capacitance of each sub-capacitor unit is n×C.

Similarly, the symmetrical layout structure can be performed in a resistor array, such that the working unit can be a resistor unit, and the sub-working unit can be a sub-resistor unit. With reference to FIG. 16, the sub-resistor unit R_{sub} has a first terminal X and a second terminal Y. The sub-resistor units R_{sub} of one resistor unit can be electrically connected in parallel or in series as disclosed in the capacitor array. The resistor unit has n sub-resistor units and the resistance of one resistor unit is R. The resistance of each sub-resistor unit is n×R for parallel connection. The resistance of each sub-resistor unit is R/n for series connection.

In another embodiment, the symmetrical layout structure can be performed in an inductor array, such that the working unit can be an inductor unit, and the sub-working unit can be a sub-inductor unit. With reference to FIG. 17, the sub-inductor unit L_{sub} has a first terminal X and a second terminal Y. The sub-inductor unit L_{sub} of one inductor unit can also be electrically connected in parallel or in series as disclosed in the capacitor array and resistor array. For example, the inductor unit has n sub-inductor units and the inductance of one inductor unit is L. The inductance of each sub-inductor unit is n×L for parallel connection. The inductance of each sub-inductor unit is L/n for series connection.

Regarding the placement of the sub-working units of the capacitor array, the resistor array and the inductor array, the mismatch between different capacitor units, resistor units or inductor units can be reduced.

What is claimed is:

1. A symmetrical layout structure of a semiconductor device, the symmetrical layout structure formed on a chip, performed in a (2^{M+1})×(2^{M+1}) array, and comprising 2^{M}-r working units and r dummy unit(s); and
each working unit having 2^{2+M} sub-working units continuously connected by a closed trace and arranged along the closed trace in the array, wherein M is a positive integer, r is zero or a positive integer, and each closed trace forms a parallelogram that is symmetrical to a diagonal path of the array.

2. The symmetrical layout structure as claimed in claim 1, wherein each of the working units is a current cell, and each of the sub-working units is a sub-current cell.

3. The symmetrical layout structure as claimed in claim 1, wherein each of the working units is a capacitor unit, and each of the sub-working units is a sub-capacitor unit.

4. The symmetrical layout structure as claimed in claim 1, wherein each of the working units is a resistor unit, and each of the sub-working units is a sub-resistor unit.

5. The symmetrical layout structure as claimed in claim 1, wherein the working unit is an inductor unit, and the sub-working unit is a sub-inductor unit,

6. The symmetrical layout structure as claimed in claim 1, wherein p1 M is 2, such that the array is an 8×8 array, and each of the working units has 16 sub-working units;
a position of each sub-working unit is represented as (x, y), wherein x is a row number of the array and y is a column number of the array; and
the diagonal path goes through the sub-working units located at the positions (1, 8) and (8, 1).

7. The symmetrical layout structure as claimed in claim 6, wherein the 16 sub-working units of a first working unit are respectively located at the positions (8, 1), (8, 2), (7, 3), (6, 4), (5, 5), (4, 6), (3, 7), (2, 8), (1, 8), (1, 7), (2, 6), (3, 5), (4, 4), (5, 3), (6, 2) and (7, 1);
the 16 sub-working units of a second working unit are respectively located at the positions (8, 3), (8, 4), (7, 5), (6, 6), (5, 7), (4, 8), (3, 8), (2, 7), (1, 6), (1, 5), (2, 4), (3, 3), (4, 2), (5, 1), (6, 1) and (7, 2); and
the 16 sub-working units of a third working unit are respectively located at the positions (8, 5), (8, 6), (7, 7), (6, 8), (5, 8), (4, 7), (3, 6), (2, 5), (1, 4), (1, 3), (2, 2), (3, 1), (4, 1), (5, 2), (6, 3) and (7, 4).

8. The symmetrical layout structure as claimed in claim 1, wherein M is 3, such that the array is a 16×16 array, and each of the working units has 32 sub-working units;
a position of each sub-working unit is represented as (x, y), wherein x is a row number of the array and y is a column number of the array; and
the diagonal path goes through the sub-working units located at the positions (1, 16) and (16, 1).

9. The symmetrical layout structure as claimed in claim 8, wherein the 32 sub-working units of a first working unit are respectively located at the positions (16, 1), (16, 2), (15, 3), (14, 4), (13, 5), (12, 6), (11, 7), (10, 8), (9, 9), (8, 10), (7, 11), (6, 12), (5, 13), (4, 14), (3, 15), (2, 16), (1, 16), (1, 15), (2, 14), (3, 13), (4, 12), (5, 11), (6, 10), (7, 9), (8, 8), (9, 7), (10, 6), (11, 5), (12, 4), (13, 3), (14, 2) and (15, 1);
the 32 sub-working units of a second working unit are respectively located at the positions (16, 3), (16, 4), (15, 5), (14, 6), (13, 7), (12, 8), (11, 9), (10, 10), (9, 11), (8, 12), (7, 13), (6, 14), (5, 15), (4, 16), (3, 16), (2, 15), (1, 14), (1, 13), (2, 12), (3, 11), (4, 10), (5, 9), (6, 8), (7, 7), (8, 6), (9, 5), (10, 4), (11, 3), (12, 2), (13, 1), (14, 1) and (15, 2);
the 32 sub-working units of a third working unit are respectively located at the positions (16, 5), (16, 6), (15, 7), (14, 8), (13, 9), (12, 10), (11, 11), (10, 12), (9, 13), (8, 14), (7, 15), (6, 16), (5, 16), (4, 15), (3, 14), (2, 13), (1, 12), (1, 11), (2, 10), (3, 9), (4, 8), (5, 7), (6, 6), (7, 5), (8, 4), (9, 3), (10, 2), (11, 1), (12, 1), (13, 2), (14, 3) and (15, 4);
the 32 sub-working units of a fourth working unit are respectively located at the positions (16, 9), (16, 10), (15, 11), (14, 12), (13, 13), (12, 14), (11, 15), (10, 16l ), (9, 16), (8, 15), (7, 14), (6, 13), (5, 12), (4, 11), (3, 10), (2, 9), (1, 8), (1, 7), (2, 6), (3, 5), (4, 4), (5, 3), (6, 2), (7, 1), (8, 1), (9, 2), (10, 3), (11, 4), (12, 5), (13, 6), (14, 7) and (15, 8);
the 32 sub-working units of a fifth working unit are respectively located at the positions (16, 11), (16, 12), (15, 13), (14, 14), (13, 15), (12, 16), (11, 16), (10, 15), (9, 14), (8, 13), (7,12), (6, 11), (5, 10), (4, 9), (3, 8), (2, 7), (1, 6), (1, 5), (2, 4), (3, 3), (4, 2), (5, 1), (6, 1), (7, 2), (8, 3), (9, 4), (10, 5), (11, 6), (12, 7), (13, 8), (14, 9) and (15, 10);
the 32 sub-working units of a sixth working unit are respectively located at the positions (16, 13), (16, 14), (15, 15), (14, 16), (13, 16), (12, 15), (11, 14), (10, 13), (9, 12), (8, 11), (7, 10), (6, 9), (5, 8), (4, 7), (3, 6), (2, 5), (1, 4), (1, 3), (2, 2), (3, 1), (4, 1), (5, 2), (6, 3), (7, 4), (8, 5), (9, 6), (10, 7), (11, 8), (12, 9), (13, 10), (14, 11) and (15, 12); and
the 32 sub-working units of a seventh working unit are respectively located at the positions (16, 15), (16, 16), (15, 16), (14, 15), (13, 14), (12, 13), (11, 12), (10, 11), (9, 10), (8, 9), (7, 8), (6, 7), (5, 6), (4, 5), (3, 4), (2, 3), (1, 2), (1, 1), (2, 1), (3, 2), (4, 3), (5, 4), (6, 5), (7, 6), (8, 7), (9, 8), (10, 9), (11, 10), (12, 11), (13, 12), (14, 13) and (15, 14).

10. The symmetrical layout structure as claimed in claim 2, wherein each sub-current cell is composed of electric switches and current sources.

11. The symmetrical layout structure as claimed in claim 10 further comprising least significant bits composed of multiple current cells.

12. The symmetrical layout structure as claimed in claim 11, wherein the current cells of the least significant bits are located at position(s) of the dummy unit(s).

13. The symmetrical layout structure as claimed in claim 2, wherein the sub-current cells of each current cell are electrically connected in parallel.

14. The symmetrical layout structure as claimed in claim 3, wherein the sub-capacitor units of each capacitor unit are electrically connected in parallel or in series.

15. The symmetrical layout structure as claimed in claim 4, wherein the sub-resistor units of each resistor unit are electrically connected in parallel or in series.

16. The symmetrical layout structure as claimed in claim 5, wherein the sub-inductor units of each inductor unit are electrically connected in parallel or in series.
